(19) United States
(12) Patent Application Publication
(10) Pub. No.: US 2008/0157200 A1
(43) Pub. Date: Jul. 3, 2008

(54) STRESS LINER SURROUNDED FACETLESS EMBEDDED STRESSOR MOSFET

(75) Inventors: Byeong Y. Kim, Lagrangeville, NY (US); Shahid A. Butt, Ossining, NY (US); Xiaomeng Chen, Poughkeepsie, NY (US); Shwu-Jen J. Jeng, Wappingers Falls, NY (US); Hasan M. Nayfeh, Poughkeepsie, NY (US); Deepal Wehella-Gamage, Newburgh, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/616,730

(22) Filed: Dec. 27, 2006

(51) Int. Cl. H01L 29/78

(52) U.S. Cl. 257/347; 257/E29.261

(57) ABSTRACT

The present invention provides an STI bounded transistor structure having enhanced performance which is not diminished due to embedded stressor facets that can be present at the edge of the source/drain regions that contacts an embedded stressor material. Considering that the facet in the prior art is due to an STI divot formed during several necessary wet etching processes, the MOSFET source/drain edge of the inventive structure is surrounded by a liner to prevent facet growth during the epitaxial growth of the stressor material. As such, a part of the semiconductor substrate edge is preserved. The liner employed in the present invention is a stress engineering material such as, for example, silicon nitride.

### FIELD OF THE INVENTION

The present invention relates to a semiconductor structure, and more particularly to a metal oxide semiconductor field effect transistor (MOSFET) having enhanced performance.

### BACKGROUND OF THE INVENTION

Mechanical stresses within a semiconductor device substrate have been widely used to modulate and/or boast device performance. For example, in common Si technology, the channel of a transistor is oriented along the <110> direction on {100} planes of silicon. In this arrangement, hole mobility is enhanced when the channel is under compressive stress in the current flow direction and/or under tensile stress in a directional normal of the channel, while electron mobility is enhanced when the channel is under tensile stress in both parallel and normal direction of channel. Therefore, compressive and/or tensile stresses can be advantageously created in the channel regions of a p-channel field effect transistor (pFET) and/or an n-channel field effect transistor (nFET) in order to enhance the performance of such a device.

One possible approach for creating a desirable stressed silicon channel is to form embedded SiGe or Si:C stressors at the source and drain regions of a MOSFET to induce compressive or tensile strain in the channel region that is located between the source and drain regions. However, due to the epitaxial process nature of forming such stressors, the edge of shallow trench isolation (STI) bounded transistors contains stressor facets that diminish the benefit of the embedded stressor. Since many critical devices are STI bounded, maintaining the performance of STI bounded transistors is important for overall device enhancement.

In view of the above, there is a need for providing a semiconductor structure, particularly a MOSFET, in which the performance of STI bounded transistors is maintained.

### SUMMARY OF THE INVENTION

The present invention provides an STI bounded transistor structure having enhanced performance which is not diminished due to embedded stressor facets that can be present at the edge of the source/drain regions that contacts an embedded stressor material.

Considering that the facets in the prior art are due to an STI divot formed during several necessary wet etching processes, the MOSFET source/drain edge of the inventive structure is surrounded by a liner to prevent facet growth during the epitaxial growth of the stressor material As such, a part of the semiconductor substrate edge is preserved. The liner employed in the present invention is a stress engineering material such as, for example, silicon nitride.

In another embodiment of the present invention, the upper sidewalls of the recessed semiconductor layer used in forming the embedded stressor regions as well as the upper sidewalls of the trenches used in defining the location of the STI have a nitride spacer that sticks out from the sidewalls. In this particular structure, the remaining semiconductor rim can hold the stress of the embedded stressor material. As such, there is no strain relaxation due to the presence of the ‘soft’ trench dielectric material.

In general terms, the inventive structure comprises:

a semiconductor substrate including at least one metal oxide semiconductor field effect transistor (MOSFET) located on a surface of said semiconductor substrate;

an embedded stressor material located at a footprint of each of said MOSFETs in a recessed area of semiconductor substrate; and

at least one trench isolation region located in said semiconductor substrate abutting said embedded stressor material, wherein said at least one trench isolation region is lined with a stress liner thereby preventing embedded stressor facet growth at the boundary between the at least one trench isolation region and the embedded stressor material.

In another embodiment of the present invention, the inventive structure comprises:

a semiconductor substrate including at least one metal oxide semiconductor field effect transistor (MOSFET) located on a surface of said semiconductor substrate;

an embedded stressor material located at a footprint of each of said FETs in a recessed area of said semiconductor structure;

at least one trench isolation region located in said semiconductor substrate abutting said embedded stressor material, wherein said at least one trench isolation region is lined with a stress liner thereby preventing embedded stressor facet growth at the boundary between the at least one trench isolation region and the embedded stressor material; and

a nitride spacer that sticks out from upper sidewalls of said recessed area that contains said embedded stressor material as well as upper sidewalls of trenches used in defining the at least trench isolation region.

### BRIEF DESCRIPTION OF THE DRAWINGS

FIGS. 1A-1I are pictorial representations (through cross sectional views) depicting the basic processing steps in accordance with a first embodiment of the present invention.

FIGS. 2A-2C are pictorial representations (through cross sectional views) depicting the basic processing steps in accordance with a second embodiment of the present invention.

### DETAILED DESCRIPTION OF THE INVENTION

The present invention, which provides a stress liner surrounded facetless embedded stressor MOSFET and a method of fabricating the same, will now be described in greater detail by referring to the following description and drawings that accompany the present application. It is noted that the drawings of the present application are provided for illustrative purposes and, as such, they are not drawn to scale.

In the following description, numerous specific details are set forth, such as particular structures, components, materials, dimensions, processing steps and techniques, in order to provide a thorough understanding of the present invention However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As stated above, the present invention provides an STI bounded transistor structure having enhanced performance which is not diminished due to embedded stressor facets that can be present at the edge of the source/drain regions that contacts an embedded stressor material. In the present invention, the MOSFET source/drain edge is surrounded by a liner to prevent facet growth during the epitaxial growth of the stressor material. As such, a part of the semiconductor substrate edge is preserved. The liner employed in the present invention is a stress engineering material such as, for example, silicon nitride.

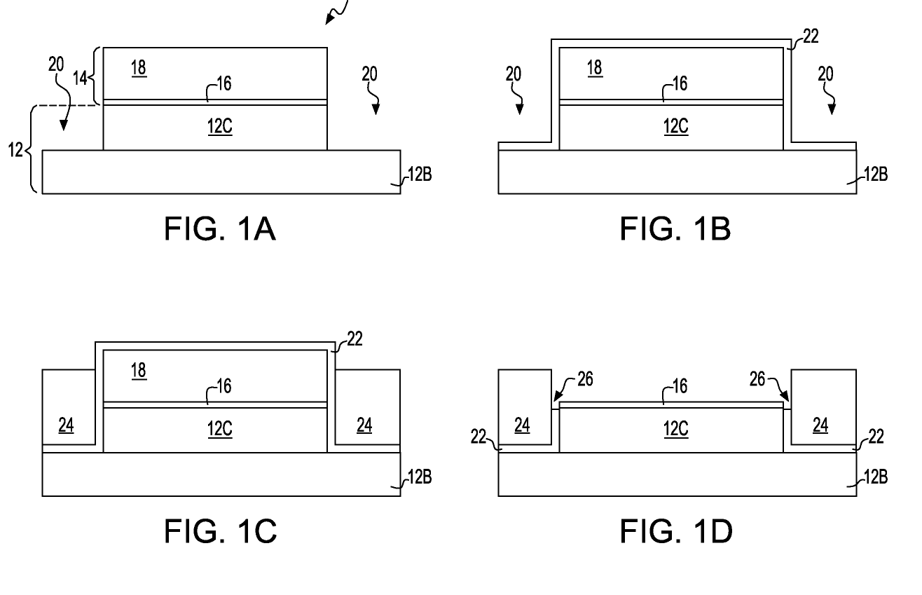

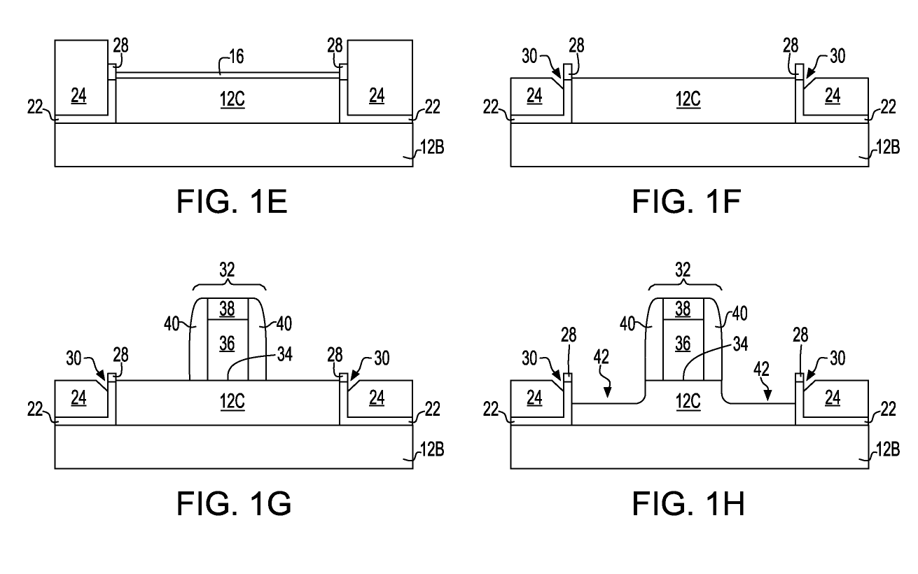

In particular, a semiconductor structure is provided as shown in FIG. 1I that comprises a semiconductor substrate 12 including at least MOSFET 32 located on a surface of the semiconductor substrate 12. An embedded stressor material 44 is located at a footprint (i.e., in the source/drain region) of each of the MOSFETs 32 in a recessed area of the substrate. The inventive structure also includes at least one trench isolation region 50 located in the semiconductor substrate 12 abutting the embedded stressor material 44. In the inventive structure, the at least one trench isolation region 50 is lined with a stress liner 22 which prevents embedded stressor facet growth at the boundary between the at least one trench isolation region and the embedded stressor material.

Reference is first made to FIGS. 1A-1I which illustrates a first embodiment of the present invention. This first embodiment of the present invention begins by providing the initial structure 10 shown in FIG. 1A. Specifically, the initial structure 10 includes a structure in which an upper portion of the semiconductor substrate 12 has been patterned utilizing a patterned pad material stack 14 as an etch mask. This step of the present invention represents an initial step in defining trenches 20 for subsequently housing the trench isolation regions. The patterned pad material stack 14 is comprised of a pad oxide 16 and a pad nitride 18.

The initial structure 10 includes materials that are well known to those skilled in the art and it is fabricated utilizing techniques that are also well known in the art.

The semiconductor substrate 12 includes any semiconductor material including, for example, Si, SiGe, SiGeC, SiC, Ge alloys, GaAs, InAs, InP and other III/IV or II/VI compound semiconductors. The semiconductor substrate 12 may be a bulk substrate, a layered substrate (such as Si/SiGe or a semiconductor-on-insulator (SOI)) or a hybrid substrate that has surface regions of different crystallographic orientation. A preferred semiconductor material for substrate 12 is a Si-containing semiconductor. In the drawings, the substrate 12 is a semiconductor-on-insulator wherein the buried oxide layer 12B and the upper semiconductor layer 12C are shown. A lower semiconductor layer (not shown) would be present beneath the buried oxide layer 12B.

The substrate 12 may be strained, unstrained or contain regions of strain and unstrain therein. The substrate 12 may also be undoped, doped or contain doped regions and undoped regions.

The substrate 12 may be formed utilizing conventional techniques well known to those skilled in the art. For example, a SIMOX process or a wafer bonding process can be used in forming a SOI substrate.

The pad material stack 14 is then formed atop the upper most surface of the substrate 12 utilizing a conventional deposition process and/or a thermal growing technique. A photoresist is then applied to the uppermost layer of the pad material stack 14 and then lithography is used to pattern the photoresist. Etching (drying and/or wet chemical etching) is then used to transfer the pattern from the patterned photoresist to the material stack 14 and then into the substrate 12. In the embodiment shown, the etching stops atop the upper surface of the buried oxide 12B. It is noted that the patterned photoresist can be stripped anytime after the pattern has been transferred into the pad material stack 14.

Next, and as such in FIG. 1B a stress liner 22 is formed on all exposed surfaces of the structure. The stress liner 22 comprises a compressively stressed dielectric material or a tensiley stressed dielectric material. Typically, the stress liner 22 is comprised of silicon nitride. The stress liner 22 is formed utilizing any conventional deposition process including, for example, a low pressure chemical vapor deposition process, a plasma enhanced chemical vapor deposition process or a high density plasma deposition process. The thickness of the stress liner 22 may vary depending on the material employed as well as the exact method used in forming the same. Typically, the stress liner 22 has a thickness from about 5 to about 30 nm.

FIG. 1C illustrates the structure after filling the trenches 20, which are now lined with stress liner 22, with a trench dielectric material 24. Typically, the trench dielectric material 24 is an oxide such as silicon dioxide. The filling of the trenches 20 may be performed utilizing any conventional deposition process such as, for example, a high-density plasma density. A planarization process may be used following the deposition process and the height of the trench dielectric material 24 can be adjusted by conducting a timed chemical etching process that recesses the trench dielectric material 24 below an upper surface of the pad material stack 14. It is noted that the trenches 20 and trench dielectric material 24 form trench isolation regions 50 in the inventive structure. The trench isolation regions are typically shallow trench isolation regions.

FIG. 1D illustrates the structure after portions of the stress liner 22 and the patterned pad nitride 18 of the patterned pad material stack 14 have been removed utilizing an etching process that selectively removes nitride as compared to oxide. As is shown in the drawing, a first divot 26 forms between the trench dielectric material 24, the stress liner 22 and the patterned pad oxide 16 during this step of the present invention.

FIG. 1E illustrates the structure after filling the first divot 26 with a dielectric spacer 28. The dielectric spacer 28 is typically a nitride or oxynitride. Preferably, silicon nitride is used as the dielectric spacer 28. The dielectric spacer 28 is formed utilizing any conventional deposition process including chemical vapor deposition or plasma enhanced chemical vapor deposition.

FIG. 1F illustrates the structure that is formed after removing the patterned pad oxide 16 utilizing an etching process that selectively removes oxide. Note that since an oxide etach is employed, the dielectric trench material 24, which is also typically an oxide, is recessed at this point of the present invention. Due to this recess of the dielectric trench material 24 a second divot 30 forms as shown in FIG. 1F.

FIG. 1G illustrates the structure after forming at least one metal oxide semiconductor field effect transistor (MOSFET) 32 on the now exposed surface of substrate 12. The at least one MOSFET 32 can be formed by deposition, lithography and etching or a replace gate process can be used in forming the same. Each MOSFET formed includes a gate dielectric 34, a gate conductor 36, an optional dielectric cap 38 and a gate spacer 40.

The gate dielectric 34 of each transistor may be the same or different insulating material including, for example, oxides, nitrides, oxynitrides and multilayer stacks of any of these insulators. Preferably, an oxide such as, but not limited to, silicon dioxide, is used as the gate dielectric. The gate conductor of each transistor comprises any conductive material including doped polySi, doped SiGe, an elemental metal, an alloy of an elemental metal, a metal silicide or any multilayered stack thereof (e.g., a stack of a metal silicide located atop a polySi base). Preferably, polySi gate conductors are employed. The optional dielectric cap 38 comprises an oxide, nitride or oxynitride. The gate spacer of each transistor includes an oxide, nitride, oxynitride and multilayers stacks thereof. Preferably, the spacer is an oxide or nitride of silicon.

Following the formation of the structure shown in FIG. 1G, the exposed portions of the semiconductor substrate 12, e.g., the upper semiconductor layer 12C, is recessed utilizing an etching process that selectively removes semiconductor material providing the structure shown in FIG. 1H. The recessed area 42 formed in the substrate 12 is located at the footprint of the MOSFET 32.

FIG. 1I illustrates the structure that is formed after filling the recessed area 42 with a embedded stressor material 44. The embedded stressor material is formed utilizing an epitaxial growth step which grows a semiconductor material in the recessed area. The embedded stressor material 44 may be comprised of SiGe or Si:C.

Following the formation of the embedded stressor material 44, conventional MOSFET processing techniques such as, for example, forming source/drain regions in the embedded semiconductor material 44, and forming silicide contacts atop the source/drain regions can be performed.

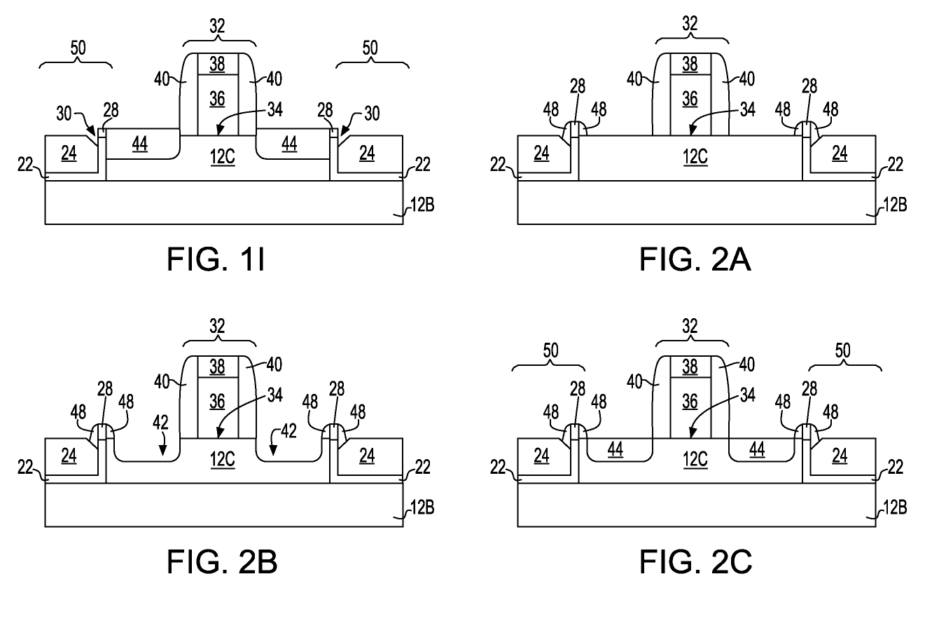

FIGS. 2A-2C illustrates a second embodiment of the present invention. The second embodiment includes a nitride spacer that sticks out from the upper sidewalls of the recessed semiconductor layer used in forming the embedded stressor regions as well as the upper sidewalls of the trenches used in defining the location of the trench isolation regions.

The second embodiment of the present invention begins by first providing the structure shown in FIG. 1E. It is noted that the nitride spacer 28 of the second embodiment is taller (i.e., has a greater height) than the nitride spacer 28 employed in the first embodiment. As a result, the spacer 48 is formed at same time as that of spacer 40 shown in FIG. 2A; there are no additional processing steps needed to form spacer 48.

Next, as shown in FIG. 2B, the exposed surfaces of the substrate 12 are recessed utilizing a selective etching process as described above in regard to forming the structure shown in FIG. 1H. FIG. 2C illustrates the structure after embedded stressor material is formed into the recessed area 42 of the semiconductor substrate 12 shown in FIG. 2B.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A semiconductor structure comprising:
a semiconductor substrate including at least one metal oxide semiconductor field effect transistor (MOSFET) located on a surface of said semiconductor substrate;
an embedded stressor material located at a footprint of each of said MOSFETs in a recessed area of semiconductor substrate; and
at least one trench isolation region located in said semiconductor substrate abutting said embedded stressor material, wherein said at least one trench isolation region is lined with a stress liner thereby preventing embedded stressor facet growth at the boundary between the at least one trench isolation region and the embedded stressor material.

2. The semiconductor structure of claim 1 wherein said semiconductor substrate is a semiconductor-on-insulator and said embedded stressor material and said at least one trench isolation are located in a top semiconductor layer of said semiconductor-on-insulator.

3. The semiconductor structure of claim 1 wherein said embedded stressor material is one of SiGe or Si:C.

4. The semiconductor structure of claim 1 wherein said stress liner is a compressively stressed dielectric material.

5. The semiconductor structure of claim 1 wherein said stress liner is a tensiley stressed dielectric material.

6. The semiconductor structure of claim 1 wherein said stress liner comprises silicon nitride and said embedded stressor material comprises SiGe.

7. The semiconductor structure of claim 1 wherein said at least one trench isolation region is filled with a trench dielectric material having a divot at an upper surface thereof that is adjoining said at least one trench isolation region including said stress liner.

8. A semiconductor structure comprising:
a semiconductor substrate including at least one metal oxide semiconductor field effect transistor (MOSFET) located on a surface of said semiconductor substrate;
an embedded stressor material located at a footprint of each of said FETs in a recessed area of said semiconductor structure;
at least one trench isolation region located in said semiconductor substrate abutting said embedded stressor material, wherein said at least one trench isolation region is lined wig a stress liner thereby preventing embedded stressor facet growth at the boundary between the at least one trench isolation region and the embedded stressor material; and
a nitride spacer that sticks out from upper sidewalls of said recessed area that contains said embedded stressor material as well as upper sidewalls of trenches used in defining the at least trench isolation region.

9. The semiconductor structure of claim 8 wherein said semiconductor substrate is a semiconductor-on-insulator and said embedded stressor material and said at least one trench isolation are located in a top semiconductor layer of said semiconductor-on-insulator.

10. The semiconductor structure of claim 8 wherein said embedded stressor material is one of SiGe or Si:C.

11. The semiconductor structure of claim 8 wherein said stress liner is a compressively stressed dielectric material.

12. The semiconductor structure of claim 8 wherein said stress liner is a tensiley stressed dielectric material.

13. The semiconductor structure of claim 8 wherein said stress liner comprises silicon nitride and said embedded stressor material comprises SiGe.

14. The semiconductor structure of claim 8 wherein said at least one trench isolation region is filled with a trench dielectric material having a divot at an upper surface thereof that is adjoining said at least one trench isolation region including said stress liner.
